(19) United States
(12) Patent Application Publication
(10) Pub. No.: US 2019/0181163 A1
(43) Pub. Date: Jun. 13, 2019

(54) THIN FILM TRANSISTOR AND METHOD OF FABRICATING THE SAME

(71) Applicant: Chunghwa Picture Tubes, LTD., Taoyuan City (TW)

(72) Inventors: Hsi-Ming Chang, Taoyuan City (TW); Yu-Hsien Chen, Taoyuan City (TW); Yen-Yu Huang, Taoyuan City (TW)

(73) Assignee: Chunghwa Picture Tubes, LTD., Taoyuan City (TW)

(21) Appl. No.: 15/894,931

(22) Filed: Feb. 13, 2018

(30) Foreign Application Priority Data
Dec. 11, 2017 (CN) 201711304674.0

(51) Int. Cl. H01L 27/12; H01L 23/544; H01L 29/66

(52) U.S. Cl. CPC H01L 27/1296; H01L 23/544; H01L 27/1288; H01L 27/1262; H01L 29/78654; H01L 29/66772; H01L 29/66757; H01L 2223/54426; H01L 27/1225; H01L 29/66969

(57) ABSTRACT

A thin film transistor and a method of fabricating the same are provided. The thin film transistor includes a channel layer, a source, a drain, an insulating layer and a gate. The channel layer is disposed on a substrate. The source and the drain are disposed separately on the channel layer. The insulating layer covers the source, the drain and the channel layer. The gate is disposed on the insulating layer, wherein two opposite sidewalls of the channel layer are respectively aligned to a sidewall of the source distant to the drain and a sidewall of the drain distant to the source. The thin film transistor of the invention improves the precision of alignment in the fabricating process, such that the film transistor has an excellent quality.

### CROSS-REFERENCE TO RELATED APPLICATION

This application claims the priority benefit of China application serial no. 201711304674.0, filed on Dec. 11, 2017. The entirety of the above-mentioned patent application is hereby incorporated by reference herein and made a part of this specification.

### BACKGROUND OF THE INVENTION

### Field of the Invention

The invention relates to a thin film transistor (TFT) and a method of fabricating the same, and more particularly, to a top-gate thin film transistor and a method of fabricating the same.

### Description of Related Art

The current development of liquid crystal display technology has become quite mature, and the focus of the competition among each display companies concentrates more and more on improving the quality and reducing the cost. Photolithography is an essential process in fabricating a thin film transistor. When performing an exposure, to make the patterns of each layer on the desired relative positions, an alignment mark is often disposed on a side of the substrate to guarantee the precision of alignment.

However, the alignment mark as well as the gate or the source/drain of the thin film transistor are formed by the same patterned metal layer, in a subsequent process of fabricating the thin film transistor (such as a heat treatment process), the alignment mark is easily affected and thereby causes an offset of the relative position of the gate or the source/drain of the thin film transistor, which results in the problem of poor alignment.

Therefore, how to improve the precision of alignment in the process of fabricating the thin film transistor so that the thin film transistor has an excellent quality is an issue that needs to be addressed.

### SUMMARY OF THE INVENTION

The invention provides a thin film transistor and a method of fabricating the same, wherein the precision of alignment in the process of fabricating the thin film transistor is improved such that the thin film transistor has an excellent quality.

An embodiment of the invention provides a thin film transistor including a channel layer, a source, a drain, an insulating layer and a gate. The channel layer is disposed on a substrate. The source and the drain are disposed separately on the channel layer. The insulating layer covers the source, the drain and the channel layer. The gate is disposed on the insulating layer, wherein two opposite sidewalls of the channel layer are respectively aligned to a sidewall of the source distant to the drain and a sidewall of the drain distant to the source.

According to an embodiment of the invention, the thin film transistor further includes an alignment mark disposed on the substrate and separate from the channel layer.

According to an embodiment of the invention, the alignment mark includes a conductive layer and a semiconductor layer. The semiconductor layer is disposed between the substrate and the conductive layer.

According to an embodiment of the invention, the semiconductor layer and the channel layer are formed by the same patterned semiconductor layer.

According to an embodiment of the invention, the conductive layer, the source and the drain are formed by the same patterned conductive layer.

An embodiment of the invention further provides a fabricating method of a thin film transistor, and the fabricating method includes the following steps. A channel material layer is formed on a substrate. A conductive material layer is covered on the channel material layer to form a stacked layer on the substrate. A portion of the stacked layer is removed to form an alignment mark and a patterned stacked layer separate from each other, wherein the patterned stacked layer includes a channel layer and a conductive layer formed on the channel layer. The conductive layer is patterned to form a source and a drain separate from each other, wherein the source and the drain expose a portion of the channel layer. An insulating layer is covered on the source, the drain and the channel layer. A gate is formed on the insulating layer.

According to an embodiment of the invention, before covering the conductive material layer on the channel material layer, an annealing process is performed to the channel material layer.

According to one embodiment of the invention, a method of forming the alignment mark and the patterned stacked layer separate from each other includes the following steps. A patterned photoresist layer is formed on the stacked layer, wherein the patterned photoresist layer exposes a portion of the stacked layer. The portion of the stacked layer exposed by the patterned photoresist layer is removed to form the alignment mark and the patterned stacked layer.

According to one embodiment of the invention, the first patterned photoresist layer has a first portion and a second portion, a thickness of the first portion is greater than a thickness of the second portion, and before patterning the conductive layer, the second portion of the patterned photoresist layer is removed to expose a portion of the conductive layer.

According to one embodiment of the invention, a method of forming the patterned photoresist layer includes following steps. A photoresist layer is formed on the stacked layer and a photolithography process is performed to the photoresist layer with a half tone mask (HTM) to form a patterned photoresist layer having a first portion and a second portion.

Based on the above, in the thin film transistor and the method of fabricating the same according to the above embodiments, the alignment mark and the patterned stacked layer are formed simultaneously by removing a portion of the stacked layer constituted of the channel material layer and the conductive material layer. As such, the alignment mark as well as the channel layer and conductive layer (may subsequently form a source and a drain separate from each other by another patterning process) in the patterned stacked layer are free from the problem of alignment offset; also, when performing other treatment to the channel material layer or the conductive material layer, the alignment mark remains unaffected, so the problem of poor alignment does not occur. As such, the thin film transistor has an excellent quality.

To make the aforementioned and other features and advantages of the invention more comprehensible, several embodiments accompanied with figures are described in detail below.

### BRIEF DESCRIPTION OF THE DRAWINGS

The accompanying drawings are included to provide a further understanding of the embodiment, and are incorporated in and constitute a portion of this specification. The drawings illustrate embodiments and, together with the description, serve to explain the principles of the embodiment.

FIG. 1, FIG. 2A, FIG. 2B, FIG. 3, FIG. 4, FIG. 5A, FIG. 5B, FIG. 6A, FIG. 6B, FIG. 7A and FIG. 7B are schematic views of a method of fabricating a thin film transistor according to an embodiment of the invention.

### DESCRIPTION OF THE EMBODIMENTS

Descriptions of the invention are given with reference to the exemplary embodiments illustrated by the figures. Wherever possible, the same reference numerals are used in the figures and the description to refer to the same or similar parts.

The accompanying drawings are included to provide a further understanding of the invention. Nevertheless, the invention may be embodied in many different forms and should not be construed as being limited to the embodiments set forth in the specification. A thickness of a layer and a thickness of a region may be enlarged in the drawings for the sake of clarity. The reference numerals and portion of the contents of the previous embodiment are used in the following embodiments, in which identical reference numerals indicate identical or similar components, and repeated description of the same technical contents is omitted. Please refer to the description of the previous embodiment for the omitted contents, which will not be repeated hereinafter.

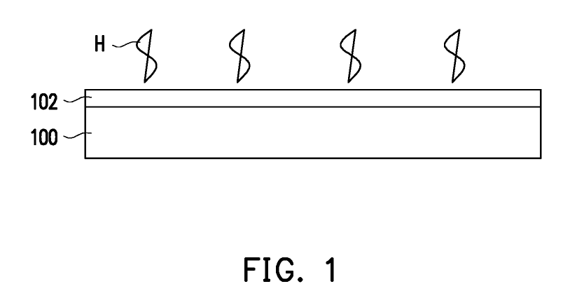

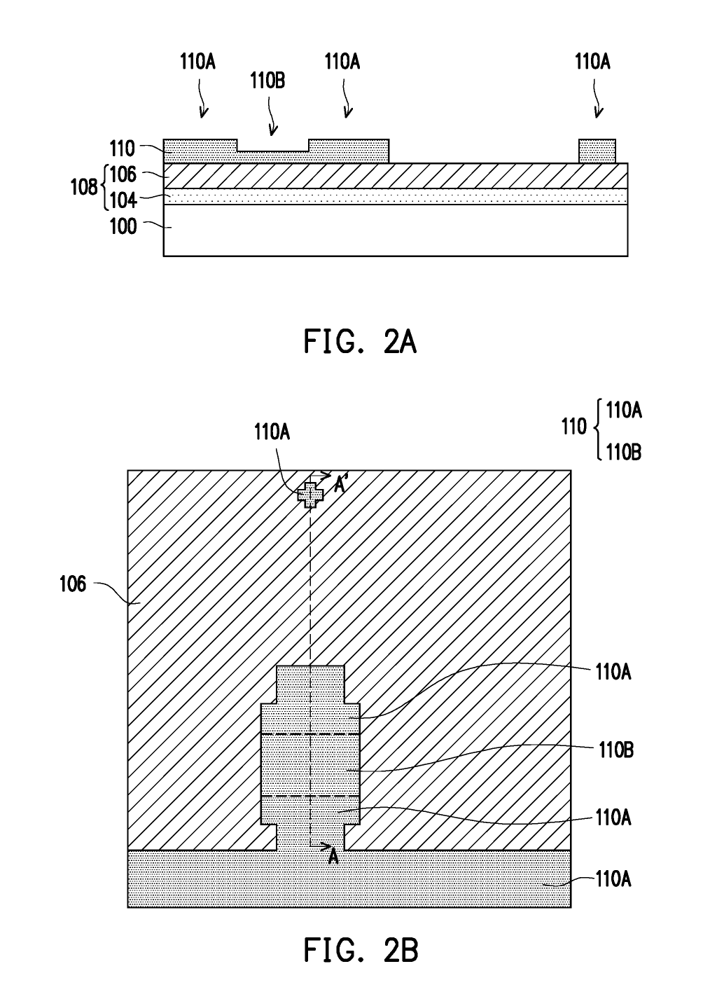

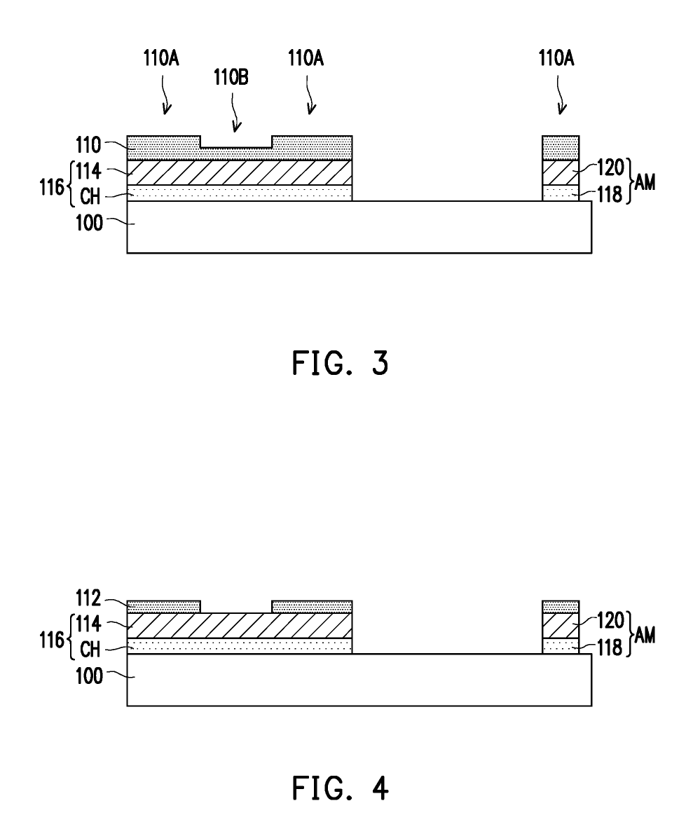

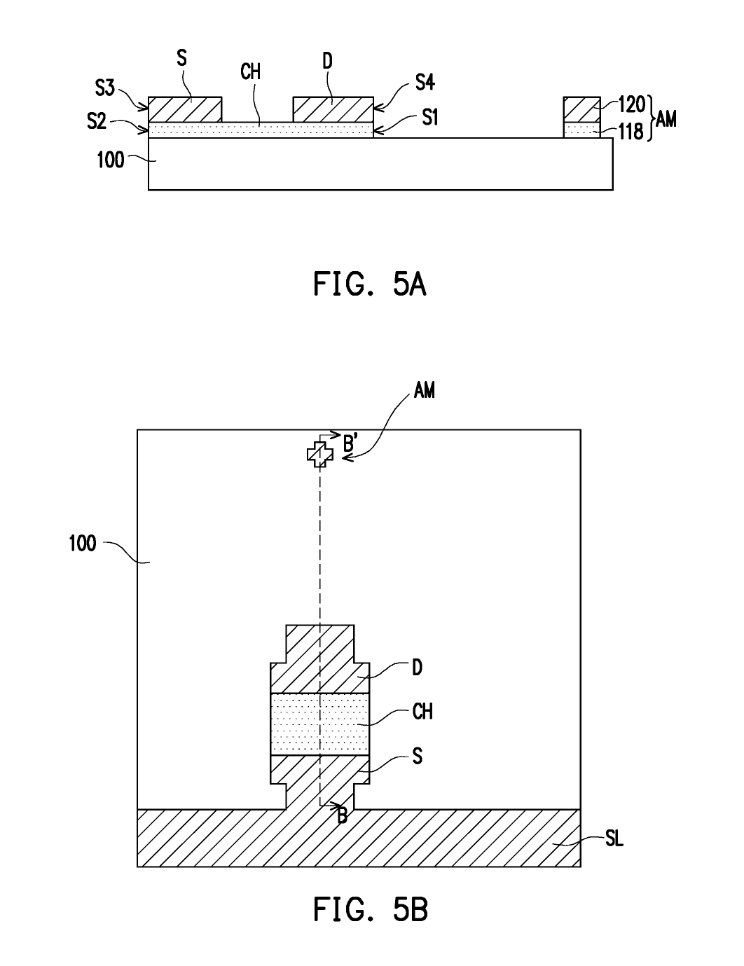

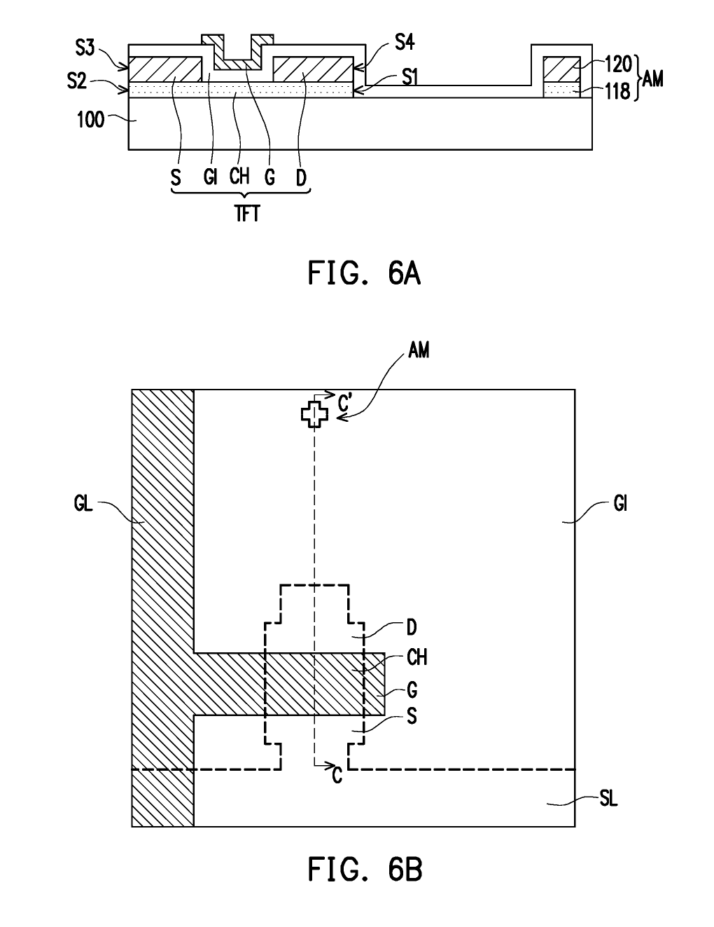

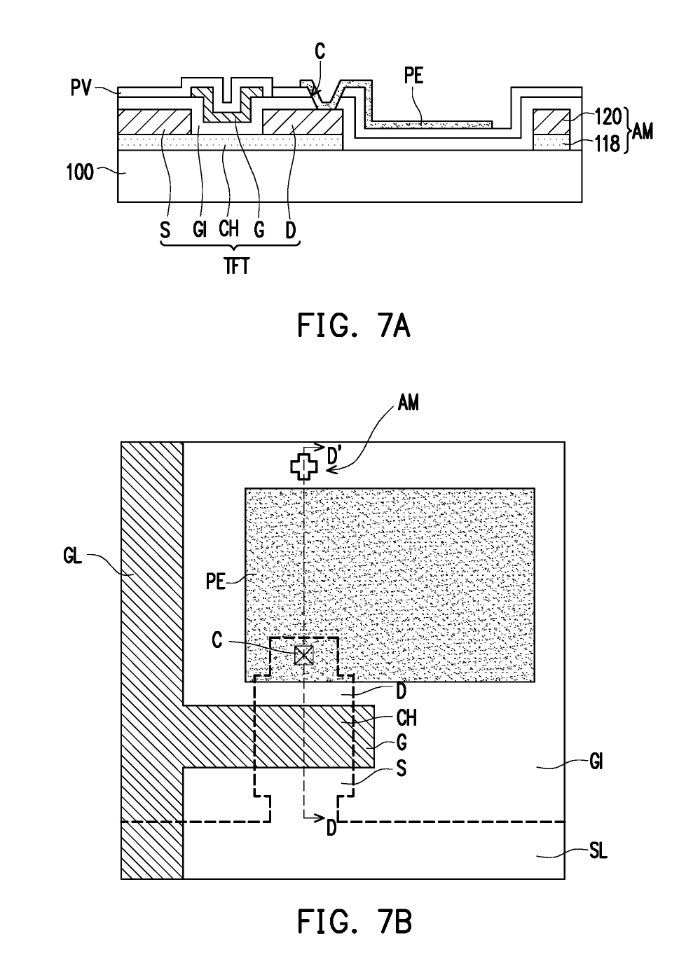

FIG. 1, FIG. 2A, FIG. 2B, FIG. 3, FIG. 4, FIG. 5A, FIG. 5B, FIG. 6A, FIG. 6B, FIG. 7A and FIG. 7B are schematic views of a method of fabricating a thin film transistor according to an embodiment of the invention. FIG. 2A is a schematic cross-sectional view taken along a line A-A′ in FIG. 2B. FIG. 5A is a schematic cross-sectional view taken along a line B-B′ in FIG. 5B. FIG. 6A is a schematic cross-sectional view taken along a line C-C′ in FIG. 6B. FIG. 7A is a schematic cross-sectional view taken along a line D-D′ in FIG. 7B. In order to clearly illustrate the relative position of the thin film transistor and a pixel electrode, a passivation layer is omitted from FIG. 7B.

Referring to FIG. 1, a channel material layer 102 is formed on a substrate 100. The substrate 100 may be a glass substrate, a quartz substrate or an organic polymeric substrate. A material of the channel material layer 102 may be a semiconductor material, such as amorphous silicon, microcrystalline silicon, monocrystalline silicon, an organic semiconductor material, an oxide semiconductor material or other suitable materials. The channel material layer 102 may be formed on the substrate 100 by a method of spin coating, slit coating, sputtering or a combination thereof. For example, the channel material layer 102 may be formed on the substrate 100 by coating a solution metal oxide semiconductor (SMO) on the substrate 100 by a method of slit coating. As such, since the SMO is coated on the substrate 100 without patterns thereon, the problem of uneven film thickness caused by flowability of the SMO at the height difference of the pattern (such as at the sides and corners of the pattern) may be avoided.

Next, an annealing process H may be performed to the channel material layer 102 optionally to improve the crystallinity of the channel material layer 102, such that in a subsequent patterning process forming a source and a drain, a channel layer (formed by patterning the channel material layer 102) has an excellent durability to an etchant used in a wet etching process. The etchant is, for example, an aluminum acid etchant, a PAN etchant or a combination thereof. In some embodiments, the PAN etchant includes phosphoric acid, acetic acid and, nitric acid. In some embodiments, the annealing process H is under a temperature of 400° C. It should be noted that, if a temperature of the annealing process H is insufficient, the crystallinity of the channel material layer may not be improved. In some embodiments, other suitable process may be further performed to the channel material layer 102 optionally.

Referring to FIG. 2A and FIG. 2B, a conductive material layer 106 is covered on the channel material layer 102 to form a stacked layer 108 on the substrate 100. In this embodiment, the conductive material layer 106 is formed on the treated channel material layer 104. A material of the conductive material layer 106 may be a metal, a metal oxide, a metal nitride or a combination thereof. For example, a material of the conductive material layer 106 may be molybdenum (Mo), aluminum (Al), titanium (Ti) or a combination thereof. In this embodiment, the conductive material layer 106 may be formed on the treated channel material layer 104 by sputtering, but the invention is not limited thereto. In other embodiments, other suitable method may also be applied to form the conductive material layer 106.

Next, a patterned photoresist layer 110 is formed on the stacked layer 108, wherein the patterned photoresist layer 110 exposes a portion of the stacked layer 108 (i.e. the conductive material layer 106 in the stacked layer 108). In this embodiment, a photolithography process may be performed to a photoresist layer (not illustrated) formed on the stacked layer 108 by a half tone mask (HTM), such that the formed patterned photoresist layer 110 has a first portion 110A and a second portion 110B, and the conductive material layer 106 may be exposed. In some embodiments, in addition to covering where an alignment mark, the source and the drain are to be formed, the first portion 110A of the patterned photoresist layer 110 further covers where a source line is to be formed, and the second portion 110B of the patterned photoresist layer 110 covers the place between where the source and the drain are to be formed. In some embodiments, a thickness of the first portion 110A is greater than a thickness of the second portion 110B.

Referring to both FIG. 2A and FIG. 3, a portion of the stacked layer 108 is removed to form an alignment mark AM and a patterned stacked layer 116 separate from each other, wherein the patterned stacked layer 116 includes a channel layer CH and a conductive layer 114 formed thereon, and the alignment mark AM includes a semiconductor layer 118 and a conductive layer 120 formed thereon. In this embodiment, the patterned photoresist layer 110 serves as a mask for removing a portion of the stacked layer 108 exposed by the patterned photoresist layer 110 in order to form the alignment mark AM and the patterned stacked layer 116. In other words, by removing the portion of the stacked layer 108 exposed by the same mask (i.e. the patterned photoresist layer 110), the formed alignment mark AM and the formed patterned stacked layer 116 are free from the problem of alignment offset. As such, the problem of poor alignment, which occurs because the alignment mark is easily affected by subsequent fabricating processes (such as performing a heat treatment process to a channel layer formed on the gate) when the alignment mark is formed at the same time as the gate is formed, may be solved. In other words, even if other additional treatment is performed to the channel material layer 102 or the conductive material layer 106, it does not affect the alignment mark AM to be formed subsequently. As such, the thin film transistor has a better process window. In some embodiments, a method of removing the portion of the stacked layer 108 may be removing the conductive material layer 106 exposed by the patterned photoresist layer 110 by wet etching using PAN as an etchant, in order to expose the channel material layer 102 located under the conductive material layer 106. Next, the aforementioned exposed channel material layer 102 is removed by wet etching or dry etching, in order to form the alignment mark AM and the patterned stacked layer 116 separate from each other. In some embodiments, a method of removing the aforementioned exposed channel material layer 102 may be wet etching using an etchant containing hydrochloric acid. In some other embodiments, a method of removing the aforementioned exposed channel material layer 102 may also be dry etching using a gas including boron trichloride (BCl₃). In some embodiments, the semiconductor layer 118 of the alignment mark AM and the channel layer CH of the patterned stacked layer 116 are formed by the same patterned semiconductor layer. In some embodiments, the conductive layer 120 of the alignment mark AM and the conductive layer 114 of the patterned stacked layer 116 (the conductive layer 114 may subsequently form a source and a drain separate from each other by another patterning process) are formed by the same patterned conductive layer.

Referring to both FIG. 3 and FIG. 4, the second portion 110B of the patterned photoresist layer 110 is removed to expose a portion of the conductive layer 114. In some embodiments, since a thickness of the first portion 110A is greater than a thickness of the second portion 110B, an ashing process may be performed to both the first portion 110A and the second portion 110B of the patterned photoresist layer 110 at the same time in order to remove the second portion 110B and to reduce the thickness of the first portion 110A at the same time. As such, the thinned first portion 110A constructs a patterned photoresist layer 112 exposing the portion of the conductive layer 114. As such, it is not required to fabricate a mask for forming the source and the drain by another patterning process, so the problem of poor alignment does not occur.

Referring to FIG. 4, FIG. 5A and FIG. 5B, the portion of the conductive layer 114 exposed by the patterned photoresist layer 112 is removed using the patterned photoresist layer 112 as a mask, in order to form a source S and a drain D separate from each other as well as a source line SL connected to the source S and to expose the channel layer CH. As such, a pattern of the patterned photoresist layer 112 is generally similar to a pattern of the patterned photoresist layer 110, and the only difference therebetween is that the second portion 110B of the patterned photoresist layer 110 is removed from the patterned photoresist layer 112. That is to say, the pattern of the first portion 110A of the patterned photoresist layer 110 is similar to the pattern of the patterned photoresist layer 112 (the only difference therebetween lies in the different thickness); thus, when forming the source S and the drain D separate from each other by using the patterned photoresist layer 112 as the mask, two opposite sidewalls S1 and S2 of the channel layer CH are respectively aligned to a sidewall S3 of the source S distant to the drain D and to a sidewall S4 of the drain D distant to the source S.

Next, after the conductive layer 114 exposed by the patterned photoresist layer 112 is removed (i.e. after the patterned conductive layer 114 is removed), the patterned photoresist layer 112 may be removed by an ashing process. In some embodiments, the channel layer CH exposed by the source S and the drain D is located therebetween. In some embodiments, the conductive layer 120 of the alignment mark AM, the source S and the drain D are formed by the same patterned conductive layer. In some embodiments, the source S and the source line SL are formed by the same patterned conductive layer.

Referring to both FIG. 6A and FIG. 6B, an insulating layer GI is covered on the source S, the drain D and the channel layer CH. In some embodiments, the insulating layer GI further covers the substrate 100 and the alignment mark AM. A material of the insulating layer GI may be an inorganic dielectric material, an organic dielectric material or a combination thereof. For example, the inorganic material may be silicon oxide, silicon nitride, silicon oxynitride or a combination thereof, and the organic material may be a polymer material, such as polyimide-based resin, epoxy-based resin, or acrylic-based resin. A method of forming the insulating layer GI may be a chemical vapor deposition method, a spin coating method or a combination thereof.

Next, a gate G and a gate line GL connected to the gate G are formed on the insulating layer GI, wherein the gate G, the insulating layer GI, the source S, the drain D and the channel layer CH constitute a thin film transistor TFT. A material of the gate G may be a conductive material, such as a metal, a metal oxide, a metal nitride and a combination thereof. For example, the gate G may be molybdenum (Mo), aluminum (Al), titanium (Ti) or a combination thereof. In some embodiments, a method of forming the gate G and the gate line GL may be forming a conductive layer (not illustrated) on the insulating layer GI by sputtering, and then patterning the conductive layer to form the gate G and the gate line GL. In some embodiments, the gate G and the gate line GL are formed by the same patterned conductive layer.

Referring to both FIG. 7A and FIG. 7B, a passivation layer PV is formed on the insulating layer GI. A material of the passivation layer PV may be an inorganic insulating material, such as silicon dioxide, silicon nitride, silicon oxynitride, and a combination thereof. A method of forming the passivation layer PV may be a chemical vapor deposition method, an atomic layer chemical vapor deposition method or a combination thereof. Next, a contact opening (corresponding to the location of a contact C) exposing the drain D is formed in the passivation layer PV and the insulating layer GI, and a conductive material is filled in the contact opening to form a contact C. A material of the contact C may be a conductive material, such as a metal, a metal oxide, a metal nitride and a combination thereof. In some embodiments, a method of forming the contact opening may be performing dry etching using a gas including carbon tetrafluoride (CF₄) and oxygen (O₂). Then, a pixel electrode PE connected to the contact C is formed on the passivation layer PV. In some embodiments, the pixel electrode PE and the contact C are formed by the same patterned conductive layer.

Following with reference to FIG. 6A and FIG. 6B are the descriptions of the thin film transistor TFT according to this embodiment of the present invention. In addition, although the thin film transistor in this embodiment is described based on the above fabricating method as an example; the invention is not limited thereto.

Referring to both FIG. 6A and FIG. 6B, the thin film transistor TFT includes the channel layer CH, the source S, the drain D, the insulating layer GI and the gate G. The channel layer CH is disposed on the substrate 110. The source S and the drain D are disposed separately on the channel layer CH. The insulating layer GI covers the source S, the drain D and the channel layer CH. The gate G is disposed on the insulating layer GI, wherein two opposite sidewalls S and S2 of the channel layer CH are respectively aligned to the sidewall S3 of the source S distant to the drain D and a sidewall S4 of the drain D distant to the source S. In some embodiments, the alignment mark AM is disposed on the substrate 100 and is separate from the thin film transistor TFT, and the alignment mark AM includes the semiconductor layer 118 and the conductive layer 120, wherein the semiconductor layer 118 is disposed between the substrate 100 and the conductive layer 120. In some embodiments, the semiconductor layer 118 and the channel layer CH are formed by the same patterned semiconductor layer. In some embodiments, the conductive layer 118, the source S and the drain D are formed by the same patterned conductive layer.

In sum of the above, in the thin film transistor and a method of fabricating the same as provided in the above embodiments, the alignment mark and the patterned stacked layer are formed simultaneously by removing a portion of the stacked layer constituted of the channel material layer and the conductive material layer. As such, the alignment mark as well as the channel layer and conductive layer (may subsequently form a source and a drain separate from each other by another patterning process) in the patterned stacked layer are free from the problem of alignment offset; also, when performing other treatment to the channel material layer or the conductive material layer, the alignment mark remains unaffected, so the problem of poor alignment does not occur. As such, the thin film transistor has an excellent quality.

It will be apparent to those skilled in the art that various modifications and variations can be made to the disclosed embodiments without departing from the scope or spirit of the invention. In view of the foregoing, it is intended that the invention covers modifications and variations provided that they fall within the scope of the following claims and their equivalents.

What is claimed is:

1. A thin film transistor, comprising:
a channel layer disposed on a substrate;
a source and a drain disposed separately on the channel layer;
an insulating layer covering the source, the drain and the channel layer; and
a gate disposed on the substrate,
wherein two opposite sidewalls of the channel layer are respectively aligned to a sidewall of the source distant to the drain and a sidewall of the drain distant to the source.

2. The thin film transistor according to claim 1, further comprising:
an alignment mark disposed on the substrate and separate from the channel layer.

3. The thin film transistor according to claim 2, wherein the alignment mark further comprises:
a conductive layer; and
a semiconductor layer disposed between the substrate and the conductive layer.

4. The thin film transistor according to claim 3, wherein the semiconductor layer and the channel layer are formed by a same patterned semiconductor layer.

5. The thin film transistor according to claim 4, wherein the conductive layer, the source and the drain are formed by a same patterned conductive layer.

6. A method of fabricating a thin film transistor, comprising:
forming a channel material layer on a substrate;
covering a conductive material layer on the channel material layer to form a stacked layer on the substrate;
removing a portion of the stacked layer to form an alignment mark and a patterned stacked layer separate from each other, wherein the patterned stacked layer comprises a channel layer and a conductive layer formed on the channel layer;
patterning the conductive layer for forming a source and a drain separate from each other, wherein the source and the drain expose a portion of the channel layer;
covering an insulating layer on the source, the drain and the channel layer; and
forming a gate on the insulating layer.

7. The method of fabricating the thin film transistor according to claim 6, further comprising:
before covering the conductive material layer on the channel material layer, performing an annealing process to the channel material layer.

8. The method of fabricating the thin film transistor according to claim 6, wherein a method of forming the alignment mark and the patterned stacked layer separate from each other comprises:
forming a patterned photoresist layer on the stacked layer, wherein the patterned photoresist layer exposes a portion of the stacked layer; and
removing the portion of the stacked layer exposed by the patterned photoresist layer to form the alignment mark and the patterned stacked layer.

9. The method of fabricating the thin film transistor according to claim 8, wherein the patterned photoresist layer has a first portion and a second portion, a thickness of the first portion is greater than a thickness of the second portion, and before patterning the conductive layer, removing the second portion of the patterned photoresist layer to expose a portion of the conductive layer.

10. The method of fabricating the thin film transistor according to claim 9, wherein a method of forming the patterned photoresist layer comprises:
forming a photoresist layer on the stacked layer and performing a photolithography process to the photoresist layer with a half tone mask to form the patterned photoresist layer having the first portion and the second portion.
